(19) United States
(12) Patent Application Publication
(10) Pub. No.: US 2024/0191396 A1
(43) Pub. Date: Jun. 13, 2024

(54) Transferable Networks and Arrays of Nanostructures

(71) Applicants: University of Copenhagen, Copenhagen K (DK); Danmarks Tekniske Universitet, Kongens Lyngby (DK)

(72) Inventors: Joachim Elbeshausen Sestoft, Copenhagen Ø (DK); Thomas Kanne Nordqvist, Copenhagen Ø (DK); Mikelis Marnauza, Copenhagen Ø (DK); Aske Nørskov Gejl, Kgs. Lyngby (DK); Dags Olsteins, Copenhagen Ø (DK); Kasper Grove-Rasmussen, Copenhagen Ø (DK); Jesper Nygård, Copenhagen Ø (DK)

(21) Appl. No.: 18/285,099

(22) PCT Filed: Mar. 31, 2022
(86) PCT No.: PCT/EP2022/058694

§ 371 Date: Sep. 29, 2023

(30) Foreign Application Priority Data
Mar. 31, 2021 (EP) 21166200.2

(51) Int. Cl. C30B 29/60; C30B 11/12; C30B 29/40; C30B 29/66; H01L 29/06; H01L 29/20; H01L 29/66; H01L 29/76; H01L 31/0352; H01L 33/06; H10N 60/12

(52) U.S. Cl. CPC C30B 29/605; C30B 11/12; C30B 29/40; C30B 29/66; H01L 29/0665; H01L 29/20; H01L 29/66977; H01L 29/7613; H01L 31/035227; H01L 33/06; H10N 60/12

(57) ABSTRACT

The present disclosure relates to a method of manufacturing a transferable lamella comprising interconnected nanostructures, the method comprising the steps of: a) providing a substrate such as a planar substrate; b) forming at least one superstructure on the substrate, said superstructure comprising a plurality of elongated nanostructures (formed e.g. by growth, deposition, and/or etching); wherein the elongated nanostructures are formed such that at least two of said nanostructures are conductively interconnected, and/or wherein at least a first layer is grown or deposited to conductively interconnect or insulate at least a part of the elongated nanostructures; c) encapsulating at least a portion of said superstructure in an encapsulating material, said portion comprising at least two interconnected nanostructures; and d) cutting the encapsulating material in a direction that intersects at least two interconnected nanostructures, thereby manufacturing a transferable lamella comprising interconnected nanostructures. The present disclosure further relates to an electronic device manufactured from one or more of the lamellas provided by the method.

The present disclosure relates to electronic devices based on transferable networks and arrays of nanostructures. In particular, the present disclosure relates to a method of manufacturing a transferable lamella comprising interconnected nanostructures.

### BACKGROUND OF INVENTION

Nanostructured materials have possible applications in many industries due to their small size and attractive properties arising in confined nanosystems. However, nanostructured materials are typically very difficult to handle on a large scale. In general, state-of-the-art nanostructured materials are often non-systematically transferred to a substrate suitable for the relevant application, prior to device integration, in order to fully exploit their inherent properties. This process makes scaling and systematic device fabrication extremely difficult as this requires manually designed circuits. Consequently, many interesting nanostructured materials such as individual nanoparticles or nanowires never meet the requirements for commercial use.

Furthermore, networks of nanostructures are typically realized through either top-down or bottom-up processing techniques, and often these techniques result in nanostructures that are dependent on the substrate and/or attached to the substrate, which limits the possible applicability of these structures. Additionally, realizing such structures through either technique typically requires extensive processing which might be invasive or limit applicability.

Therefore, the semiconductor industry demands a technique to controllably mass-produce, address and transfer nanostructures such as high purity semiconductor nanocrystals on a wafer scale. Such a technique could potentially help realize a scalable manufacturing of many different electronic and optical devices such as high efficiency solar cells, optical sensors, gas sensors, single photon emitters, and quantum transistors.

WO 2016/207415 A1 by the same applicant, discloses networks of interconnected nanostructures based on kinking of nanowires during growth. WO 2016/207415 A1 is hereby enclosed by reference in its entirety.

Xu et al., ACS Nano, Vol. 1, no. 3, 31 Oct. 2007, pages 215-227, discloses a method for fabrication of metallic nanostructures by nanoskiving, wherein a thin metallic film is embedded in an epoxy film and sectioned by an ultramicrotome.

WO 2014/165634 A2 discloses a “bottom-up” approach for realizing 3D macroporous nanoelectronic networks comprising nanowire assembly and conventional lithography.

### SUMMARY OF INVENTION

The present disclosure solves the above-mentioned demands and challenges by providing a method of manufacturing a transferable lamella comprising interconnected nanostructures.

The method comprises the steps of: providing a substrate, such as a planar substrate; forming at least one superstructure on the substrate, said superstructure comprising a plurality of elongated nanostructures; wherein the elongated nanostructures are formed e.g. by growth, deposition, and/or etching such that at least two of said nanostructures are interconnected, preferably conductively interconnected, and/or wherein at least a first layer is grown or deposited (e.g. directionally deposited) to conductively interconnect or insulate at least a part of the elongated nanostructures, and preferably wherein at least one, more preferably at least two, most preferably all, of the elongated nanostructures are formed such that they elongate away from the substrate; encapsulating at least a portion of said superstructure in an encapsulating material, said portion comprising at least two interconnected nanostructures; and cutting the encapsulating material in a direction that intersects at least two interconnected nanostructures, thereby manufacturing a transferable lamella comprising interconnected nanostructures.

According to a preferred embodiment, the superstructure is formed by growing a plurality of elongated nanostructures from the substrate such as in a direction substantially perpendicular to the substrate. In this embodiment, the nanostructures may be grown such that at least two of said nanostructures are interconnected (e.g. conductively interconnected) at least partially along their growth direction and/or interconnected (e.g. conductively interconnected) through a first layer provided on the outside of said nanostructures. As an example, the superstructure may comprise interconnected nanostructures that are conductively connected through the core, wherein the core of the nanostructures comprises a semiconductor. In this example, the superstructure may further comprise a first layer provided as an insulator, a piezoelectric material, a ferromagnetic material, or a superconducting material. As another example, the core of the nanostructures comprises an insulator and the first layer comprises a semiconductor, a superconductor, or a ferromagnetic material.

Accordingly, the presently disclosed method provides a technique to controllably mass-produce, address and transfer nanostructures, such as interconnected nanostructures, on a wafer scale. The method works for many different materials and provides a scalable method to realize high efficiency solar cells, optical sensors, gas sensors, single photon emitters, LEDs, transistors and quantum transistors. The disclosed method may be utilized to produce the device architecture for quantum transport applications such as Josephson junctions and semiconductor/superconductor hybrids in a highly scalable way.

Specifically, the presently disclosed method yields a transferable lamella comprising predefined arrays of nanostructure segments (e.g. nanopillar segments or nanocrystals), wherein the nanostructure segments are embedded in an encapsulating material, said material preferably being electrically insulating and/or optically transparent. The lamella is preferably transferable to any type of substrate. The presently disclosed method facilitates the manufacture of electrical circuits by addressing the individual nanostructures systematically using standard industrial fabrication techniques. The individual nanostructure segments can be merged together during material growth to form one or more superstructures that are preferably identical and which can be systematically repeated across a large area. This opens a route towards mass-production of fully integrated devices, wherein each subunit is readily addressed.

The present disclosure further relates to a transferable lamella comprising interconnected nanostructures, such as at least two nanopillar segments that are interconnected, in particular wherein they are electrically interconnected. Preferably, the nanostructures extend between the two opposing surfaces of the lamella, such as two cut surfaces of the lamella. The cut surfaces are typically perpendicular to the direction of the axial length of the elongated nanostructures before cutting. Typically, the cross section of any of the nanostructures, in a plane parallel to the opposing surfaces, has an aspect ratio below 100, such as below 10.

The manufactured transferable lamella may preferably be transferred to any desired substrate. Subsequent to transfer, the nanostructures of the lamella may be electrically contacted using standard nanofabrication techniques. The transferable lamellas obtained by the disclosed method may also be stacked on top of each other, optionally with one or more layers in-between. Therefore, the disclosure further relates to a stack comprising a plurality of transferable lamellas manufactured from the method disclosed herein. The stack may comprise one or more additional layers configured as ‘spacer layers’. The additional layers are preferably placed between the lamellas i.e. in order to electrically decouple the individual lamellas in the stack. The material for the spacer layers may be any of the encapsulating materials mentioned herein, preferably an electrically insulating resin.

Stacks of lamellas comprising interconnected nanostructures have multiple applications. In particular, in case the lamellas are optically transparent, a number of interesting devices may be formed from the stack of lamellas. For instance, light emitting diodes (LEDs) of different wavelengths can be stacked to form pixel units, wherein each pixel unit e.g. comprises three LEDs of colours red, green and blue to provide an RGB pixel unit as shown in FIG. 7. As an example, the stack may comprise three lamellas: a first lamella comprising one or more first LEDs configured to emit light of a first wavelength (e.g. red), a second lamella comprising one or more second LEDs configured to emit light of a second wavelength (e.g. green); and a third lamella comprising one or more third LEDs configured to emit light of a third wavelength (e.g. blue). Hence, the individual LEDs of the same wavelength are preferably provided in the same lamella. Thereby, the individual LEDs of one pixel unit may be packed more closely together compared to the case, where they are provided in a single lamella or a single layer. This has the advantage that individual pixel sizes and pixel pitches are reduced beyond the current commercial state-of-the art LED displays. In addition, the presently disclosed method facilitates the use of different diode materials in the different lamellas, such that each lamella can be optimized to provide a specific colour (e.g. InGaN for emitting blue). Another possible application of the stacked lamellas according to the present disclosure is high-efficiency solar cells known as tandem solar cells. For this purpose, materials with various bandgaps may be embedded to form p-n junction(s) in the different lamellas in order to harvest different wavelengths of the solar radiation (e.g. infra-red, visible and UV).

The present disclosure further relates to a superstructure circuit, comprising at least one lamella as exemplified herein comprising multiple interconnected nanostructures; and at least two contacts in a conductive material, configured to form an electrical connection to points of the interconnected nanostructures of the lamella.

The present disclosure further relates to an electronic device comprising at least two interconnected nanostructures embedded in an encapsulating material; and at least two metal contacts connected to the nanostructures, wherein the nanostructures and the metal contacts form an electrical connection such that the device is configured to allow an electrical current to flow through the device from one metal contact to the other via the interconnected nanostructures. An example of such a device is shown in FIG. 6. By choosing appropriate materials and environmental conditions (elaborated under detailed description), the applicant has discovered a number of interesting quantum effects in the presently disclosed electronic device, said device thereby constituting a quantum transistor. By embedding a plurality of such electronic devices in a lamella, the presently disclosed method provides a highly scalable infrastructure for production of quantum (or regular) transistors independent of substrate.

Accordingly, the presently disclosed method provides a significant improvement to existing techniques, which are either substrate dependent or focus on single structures not suitable for large scale production. This is in particular useful for applications within topological quantum computing and gatemon based superconducting qubits.

### DESCRIPTION OF DRAWINGS

FIG. 1a shows the presently disclosed method simplified to two steps: the growth of a plurality of semiconducting nanopillars, the embedding of the nanopillars and subsequent cutting of the structure to provide a transferable lamella.

FIG. 1b shows a TEM image of a lamella comprising an ordered array of cross-sections of nanopillars embedded in an encapsulating material.

FIG. 2a shows an SEM image of a plurality of nanopillars in close proximity to each other, wherein some of the nanopillars have merged together during growth.

FIG. 2b shows an SEM image of four nanopillars, wherein three of the nanopillars have merged together during growth.

FIG. 2c shows a schematic of three merged nanopillars embedded in an encapsulating material such as an epoxy-based resin.

FIG. 2d shows a schematic of three nanopillars embedded in an encapsulating material, wherein the nanopillars are interconnected through a first layer.

FIG. 2e shows a TEM image of three merged nanopillars, wherein the nanopillars merged during growth.

FIG. 2f shows a schematic of an electronic device comprising six interconnected nanopillar segments (cross-sections), wherein the nanopillars merged during the growth step.

FIG. 3a shows a schematic of an electronic device comprising an InAs nanopillar cross-section contacted by two metal contacts. The device constitutes a field effect transistor.

FIG. 3b shows an SEM image of the electronic device described in relation to FIG. 3a.

FIG. 3c shows a histogram of the two-probe resistance of a batch of 18 fabricated electronic devices similar to the one shown schematically in FIG. 3a. A majority of the devices exhibit room temperature resistances below 10 kΩ.

FIG. 3d shows a graph of the conductance of one of the electronic devices (e.g. shown in FIG. 3b) as a function of the applied backgate voltage, V_{BG}.

FIG. 4a shows an SEM image of an electronic device similar to the device shown in FIG. 3b and described in relation to FIG. 3a.

FIG. 4b shows a graph of the differential conductance versus the applied backgate potential, V_{BG} in relation to the electronic device of FIG. 4a.

FIG. 4c shows waterfall plots of differential conductance as a function of the source-drain bias, VSD (mV), and backgate voltage, in order to verify the origin of the plateaus.

FIG. 4d and FIG. 4e show schematics of the zero-bias and finite-bias case, respectively.

FIG. 5 shows a colour map of the differential conductance as a function of source-drain bias and backgate voltage.

FIG. 6a shows a schematic of an electronic device comprising two semiconducting InAs nanopillar cross-sections that are interconnected and embedded in a lamella.

FIG. 6b shows an SEM image of an electronic device similar to the one in FIG. 6a.

FIG. 6c shows a color map of differential conductance (g) measured as of function of V_{SD} and T. The conductance gap disappears smoothly as T increases above the critical temperature of Al (T_{C}˜1.2 K).

FIG. 7a shows a schematic of a stack of multiple lamellas (here exemplified with three lamellas) imaged from above. The three lamellas are stacked to form one or more pixel units, each pixel unit comprising red, green and blue (RGB) pixels.

FIG. 7b shows a side-view schematic of the stack of lamellas shown in FIG. 7a.

FIG. 8 shows a schematic of three interconnected nanostructures, wherein the nanostructures are interconnected by a first layer.

FIG. 9 shows a schematic of three interconnected nanostructures, wherein the nanostructures have merged such that they are conductively interconnected.

FIG. 10 shows a schematic of a heterostructure, wherein the first layer is provided as an insulator and electrical contacts have been provided to the structure.

FIG. 11 shows the heterostructure according to FIG. 10, however wherein electrical gates have been provided to the heterostructure.

FIG. 12 shows a schematic of a heterostructure, wherein a first layer surrounds three interconnected nanostructures and a second layer surrounds the first layer.

FIG. 13 shows a schematic of three interconnected nanostructures, wherein the nanostructures are interconnected by a first layer, and wherein a second layer (e.g. an insulator) surrounds the first layer.

FIG. 14 shows an example of a heterostructure, wherein a first layer has been grown or deposited to conductively interconnect at least a part of the elongated nanostructures (here approximately half of the interconnected structure).

FIG. 15 shows an example of a heterostructure comprising a first layer and a second layer, wherein electrical contacts and gates have been provided to the structure.

FIG. 16 shows an example of a heterostructure, wherein a first layer (e.g. a high-κ dielectric) has been grown or deposited to insulate the interconnected nanostructures.

FIG. 17 shows an example of a network of interconnected nanostructures that are merged to form a cross.

FIG. 18 shows an example of a network of interconnected nanostructures that are merged to form a ring-like structure.

FIG. 19 shows an example of a network of interconnected nanostructures that are merged to form a meta-material.

### DETAILED DESCRIPTION OF THE INVENTION

The present disclosure relates to a method of manufacturing a transferable lamella comprising interconnected nanostructures.

### Formation of Superstructure

The first step of the method is the provision of a substrate, e.g. a planar substrate, which may include any substrate, preferably a substrate suitable for growing elongated nanostructures. Examples include III/V substrates such as InAs, GaAs, GaN, GaSb, and InP, but also IV substrates such as Si, Ge, and SiGe. Other substrates such as sapphire substrates may also be utilized.

The second step of the method is the formation of at least one superstructure comprising a plurality of elongated nanostructures on the substrate, preferably wherein at least one, more preferably at least two, most preferably all, of the elongated nanostructures are formed such that they elongate away from the substrate. A superstructure should be understood herein as any structure provided on a substrate or extending from said substrate. In one embodiment, the superstructure is formed by growing a plurality of elongated nanostructures from the substrate. The growth direction may be substantially perpendicular to the substrate. The nanostructures may be grown from a planar substrate. Alternatively, they may be grown on angled ridges on the substrate. Therefore, the substrate is not necessarily planar for all purposes of the presently disclosed method.

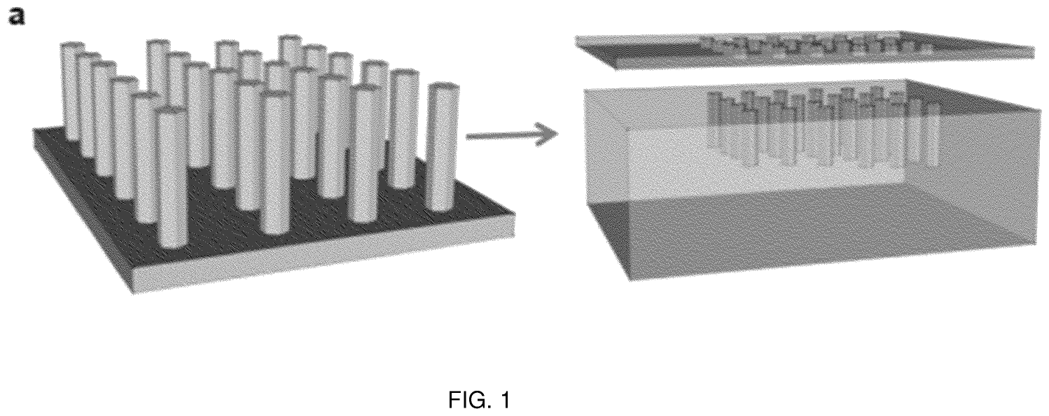

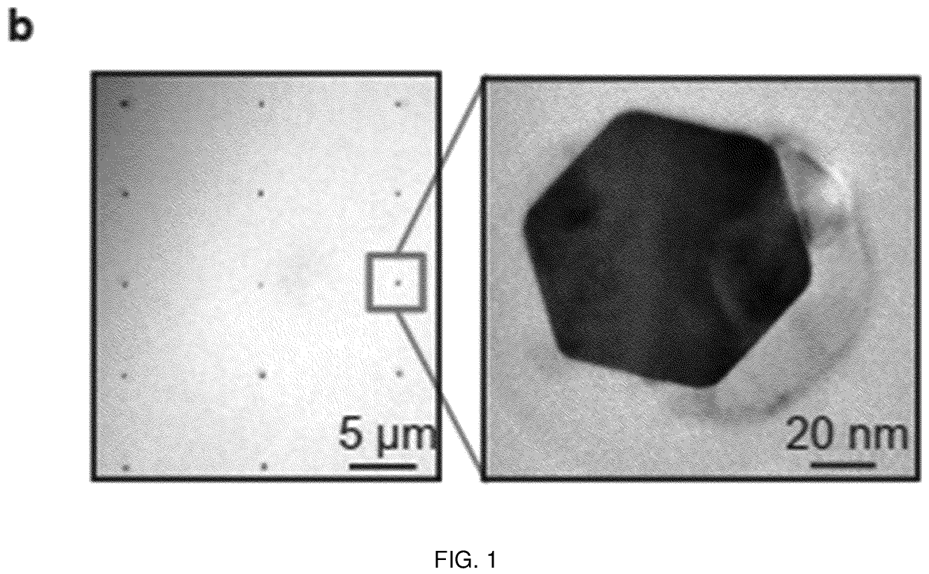

The elongated nanostructures may be grown using well-known growth techniques. Examples of growth techniques include vapour-solid-solid, vapour-phase-epitaxy, vapour-crystal-crystal, and vapour-liquid-solid (VLS). In the presently disclosed method, the VLS growth technique is preferred. When using VLS growth, metallic nanoparticle catalysts such as gold particles are positioned on the substrate. The positions of the metallic catalysts determine the initial growth positions of the elongated nanostructures from the substrate. The elongated nanostructures are preferably grown in a direction substantially perpendicular to the substrate as illustrated in FIG. 1a. The height and diameter of the elongated nanostructures can be controllably and reproducibly engineered.

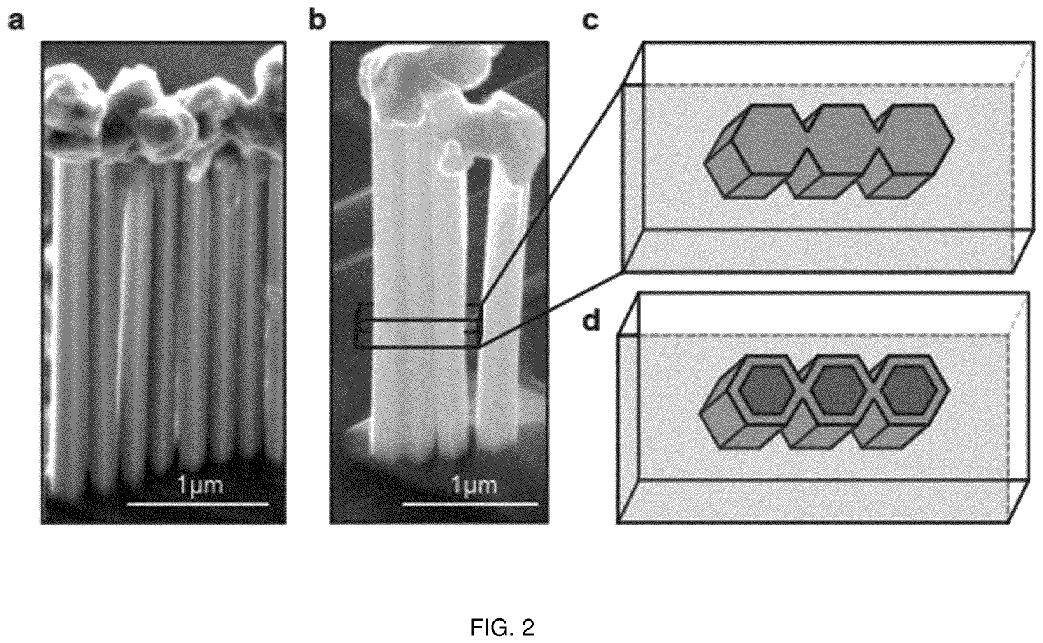

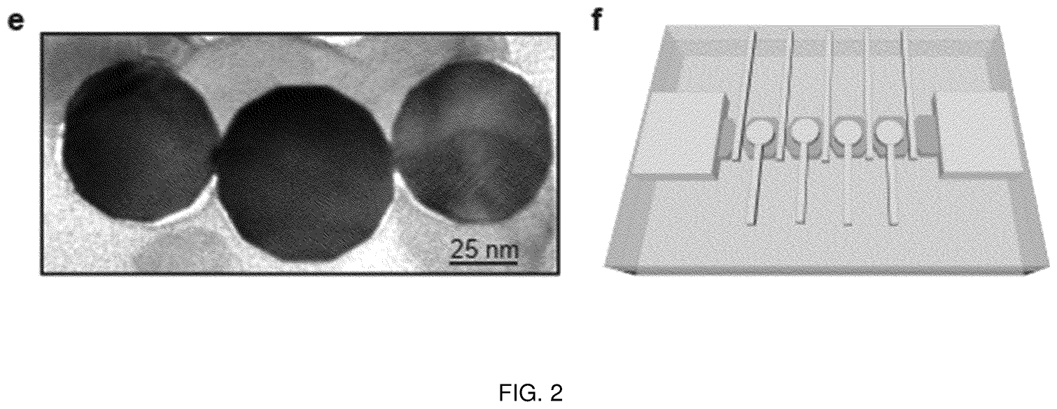

In one embodiment of the disclosed method, the elongated nanostructures are grown such that at least two of said nanostructures are conductively interconnected at least partially along their growth direction (see FIG. 2a-2b). This merging can be well controlled by adjusting a number of parameters related to the growth, such as the growth time, the substrate temperature, and/or the material fluxes. The degree of merging of the nanostructures can be characterized by the amount of overlap between two neighboring, interconnected nanostructures. The overlap, in combination with other factors such as the dimensions and materials of the nanostructures, determines the properties, e.g. the electrical properties, of the resulting interconnected nanostructures. Therefore, it is important to control the amount of overlap during the growth. The overlap between two interconnected nanostructures, in a plane parallel to the substrate, is preferably between 1 nm to 1 μm, even more preferably 1 nm to 0.5 μm.

In another embodiment of the disclosed method, at least a first layer is grown or deposited to conductively interconnect or insulate at least part of the elongated nanostructures. Hence, at least two of the nanostructures are interconnected by merging during growth as described above and/or interconnected by growth or deposition of a first layer on the outside of the nanostructures. The term ‘first layer’ should not be construed as limiting in regards to the order of the different layers. Hence, in some embodiments, other layers may be grown/deposited before the provision of a first layer. An example is the device shown in FIG. 10, wherein the electrical contacts are deposited in-situ, and the first layer is deposited subsequently, e.g. by atomic layer deposition (ALD).

In another embodiment of the disclosed method, a top-down process, such as anisotropic etching, is used to form the elongated nanostructures of the superstructure. Examples of suitable anisotropic etching techniques include reactive-ion etching (RIE), deep reactive-ion etching (DRIE). An example of a DRIE process is the Bosch process.

### Elongated Nanostructures

It is a preference that the elongated nanostructures are formed on a surface of the substrate. Typically, each nanostructure is formed on a different area, spot or point of the surface of the substrate. However, the area, spot or point of formation may also at least partly overlap.

In any way, the nanostructures are typically formed such that they elongate away from the substrate. Typically, an end of the elongated nanostructures is contacting the surface of the substrate, while the remainder of the elongated nanostructure elongates away from the surface. As such, the axial length of the elongated nanostructure may form an angle to the surface of the substrate. For example, the elongated nanostructures may be formed at an angle with respect to the surface of the substrate, such as wherein the angle is above 0°, typically the nanostructures are formed with an angle of 90° with respect to the surface of the substrate. Thus, the elongated nanostructures may be formed perpendicular to the surface of the substrate. However, it is generally preferable if said angle is at least 30°, more preferably at least 45°, yet more preferably at least 60°, even yet more preferable at least 75°, most preferable substantially 90°, such as 90°. The elongated nanostructure may thus be referred to as protruding from the surface of the substrate.

The elongated nanostructure may for example be a nanowire or

In one embodiment of the disclosed method, the elongated nanostructures are crystalline semiconductor nanostructures. An advantage of crystalline semiconductor nanostructures is that they can be grown using vapor-liquid-solid (VLS) growth, wherein a metallic nanoparticle catalysts the nanowire growth.

The elongated crystalline nanostructures may be in the form of nanopillars (crystal), nanowires (crystal), nanowhiskers (crystal), nanorods (crystal), nanosails, nanobelts, nanofins, nanospades, nanosheets, nanoflags, or nanoplates. Typically, the nanostructure has a cross section, in a plane perpendicular to its axial length, that has an aspect-ratio of 100 or below, such as wherein said cross-section is from 1 to 100, preferably wherein said aspect ratio is 10 or below, such as from 1 to 10, more preferably wherein said aspect ratio is 7 or below, such as from 1 to 7, even more preferably wherein said aspect ratio is 5 or below, such as from 1 to 5. The nanostructures may have one or more substantially plane sides, typically along its axial length, e.g. such that the nanostructures have a hexagonal cross-section, and may thereby have a cross section, in a plane perpendicular to its axial length, that is 1.

In another embodiment, the elongated nanostructures are heterostructures comprising at least two different materials. Specifically, the nanostructures may comprise a crystalline semiconductor nanostructure and a superconducting material, thereby forming a semiconductor/superconductor hybrid. The superconducting material may comprise a pure element (e.g. Al, Pb, V, Sn, or In), an alloy (e.g. NbTi or NbTiN), a ceramic such as a cuprate (e.g. YBa₂Cu₃O₇ or CuO₂), an iron-based superconductor, a covalent superconductor, or magnesium diboride (MgB₂). Examples of superconductors formed by a pure element includes: Bi, Cd, Ga, In, Hf, Hg, La, Os, Pa, Re, Ru, Tc, Ti, Tl, U, Zn, Zr, B, N, O, Mg, Ge, Y, Sm, As, F, P, Se, Gd, Ni, Pd, Ag, Pt, Au, Ac, Cr, and Eu. In particular, the following list of superconducting materials are preferred in some embodiments of the presently disclosed method: Al, Pb, NbTiN, NbTi, V, Sn, MgB₂, In, and AlPt. The superconducting material may be crystalline structured. Furthermore, it may be provided as a first layer on the outside of the semiconductor material, thereby forming an interface between the semiconductor material and the first layer. Said interface is preferably configured to induce a superconducting gap in the elongated nanostructure. A superconducting gap is an important feature for detecting and controlling quantum computation in topological systems. Networks of superconductor-semiconductor hybrid devices are important for realizing topologically protected quantum circuits based on Majorana fermions. Such networks require intersections for topological braiding operations that are needed to evolve the quantum state within the network. Thus, a quantum computational nanowire network may be provided by the presently disclosed method and/or disclosed network.

The crystalline structure of the semiconductor nanostructure may be epitaxially matched with the crystalline structure of the first layer on the interface between the two crystalline structures. Additional layers may be provided (e.g. grown or deposited) on the outside of the nanostructures and/or on the outside of the first layer. Alternatively, the elongated nanostructures are manufactured as radial heterostructures (also denoted as core-shell nanostructures), wherein the nanostructures comprise a core of a first material and a first layer of a material different from the first material. The material of the first layer may be selected from the group of superconductors, semiconductors, ferromagnetic materials, ferroinsulators, piezoelectric materials, ferroelectric materials, metals and combinations hereof.

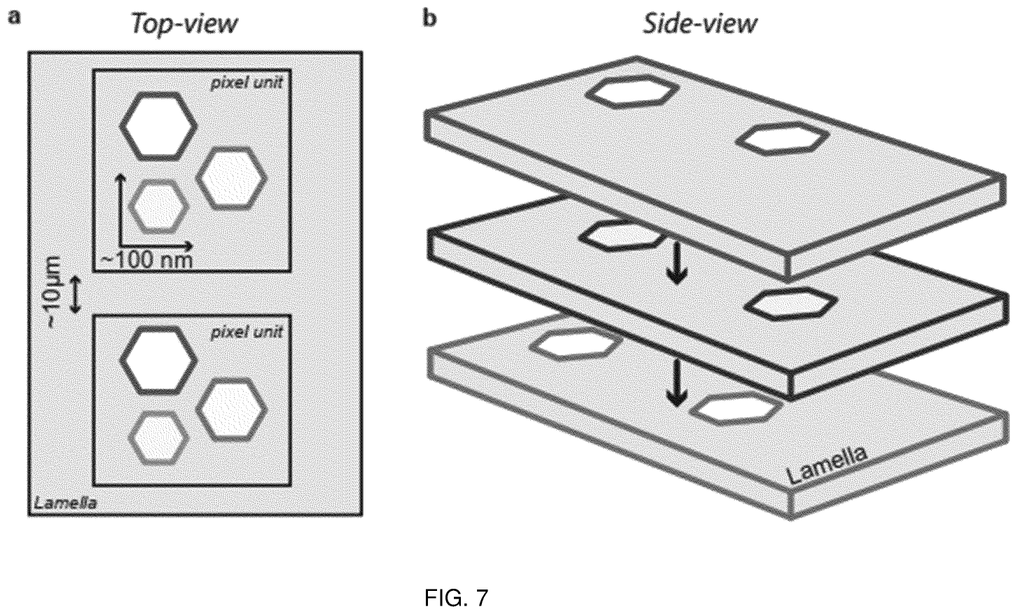

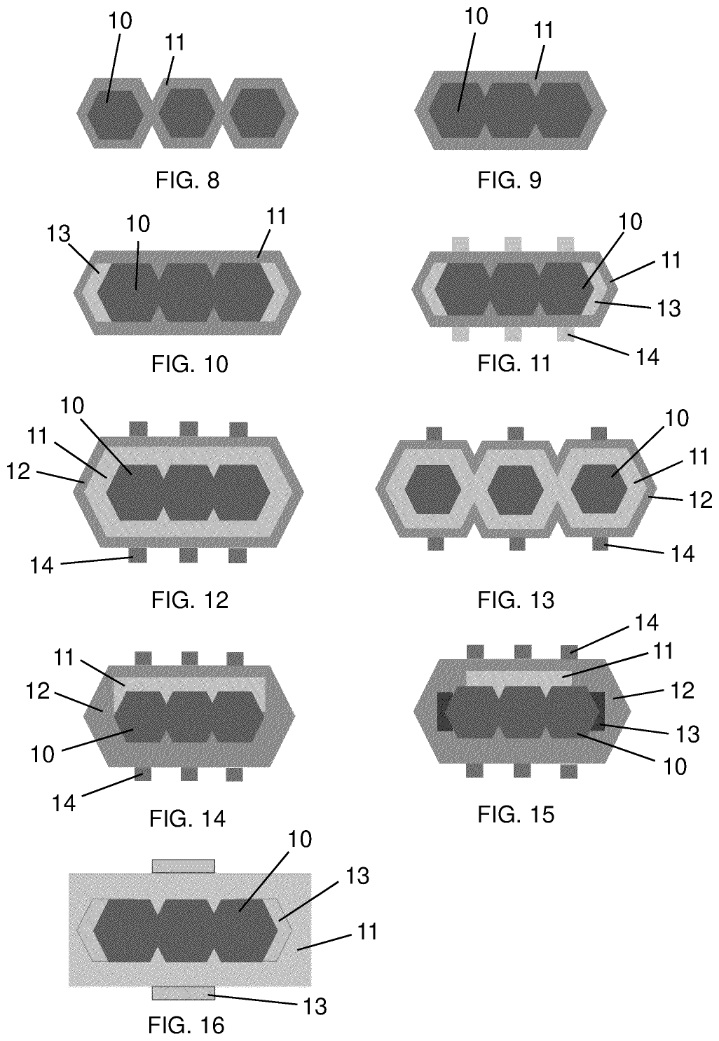

In general, the presently disclosed method facilitates the manufacture of heterostructures comprising interconnected nanostructures and a plurality of layers at least partly covering said interconnected nanostructures (said layers distributed e.g. laterally on the outside of the core of the nanostructures). In some embodiments, the nanostructures are conductively interconnected through the core of the nanostructures, i.e. wherein they have merged together during growth (examples are given in FIGS. 2a-2c, 2e, FIGS. 9-11, and FIGS. 14-16). However, in other embodiments, the nanostructures are conductively interconnected through the first layer, which is grown or deposited to conductively interconnect at least a part of the elongated nanostructures (examples are given in FIG. 8 and FIG. 13). The first layer may be fully surrounding (laterally) the core of the nanostructures or it may only partly cover at least two interconnected nanostructures. FIGS. 14-15 show schematics of heterostructures according to the present disclosure, wherein the first layer only partly covers the interconnected nanostructures. One or more additional layers may also be provided on the outside of the first layer and/or on the outside of the core of the elongated nanostructures. As an example, a second layer may be provided on the outside of the first layer, wherein said second layer is provided as an insulator (illustrated in FIGS. 12-15). The ability to use many layers of different materials with different material properties provide for a variety of different hetero nanostructures that can be achieved using the presently disclosed method. An example of a more advanced heterostructure obtainable using the disclosed method herein, comprises at least two interconnected semiconductor nanostructures (e.g. of InAs) with a first layer of a superconducting material (e.g. Al), a second layer of a ferromagnetic material (e.g. Europium (II) sulphide), and a third layer of a high-κ dielectric (e.g. Hafnium(IV) oxide).

A nanostructure (e.g. a nanopillar, a nanowire, a nanocrystal, etc.) in the form of a crystalline semiconductor nanostructure may be provided in any semiconducting material. Examples of semiconducting materials include group III-V combinations, such as InAs, InP, InSb, GaAs, GaSb, AlSb and InGaAs, or group IV elements such as Si or Ge, or group IV combinations such as SiGe, or group II-VI combinations such as ZnO, ZnSe and CdSe, or group I-VII combinations. An example of a crystalline semiconductor nanostructure is an InAs nanopillar.

The elongated nanostructures may in some embodiments be formed (e.g. grown) such that the interconnected nanostructures form at least one p-n junction in the plane of the lamella.

### Encapsulating Material

The third step of the disclosed method is the encapsulation of at least a portion (i.e. a volume) of the formed superstructure, said superstructure comprising the elongated nanostructures, in an encapsulating material. The encapsulated portion should at minimum comprise two interconnected nanostructures fully embedded therein, however it may comprise many more or the entirety of the formed superstructure. The encapsulation step is schematically shown in FIG. 2c-2d, which shows three interconnected nanopillars embedded in an encapsulating material such as a transparent resin. The encapsulating material may be selected from the group of poly(methylmethacrylate), polystyrene, polycarbonate, epoxy-based resins, such as Epon and Durcupan, low-density polyethylene and/or PDMS. Preferably, the encapsulating material has a Young's modulus of at least 1000 MPa, even more preferably at least 1500 MPa. The encapsulating material is preferably electrically insulating with a resistivity of at least 10⁷ Ω·m and/or transparent to visible light. The use of an electrically insulating encapsulating material is preferred since it provides a better electrical protection (e.g. from static electricity) for the individual nanostructures embedded therein. Furthermore, it allows electrically contacting one of the nanostructures without providing an electric current through neighbouring nanostructures. Alternatively, the encapsulating material is an electrically conducting resin, e.g. EPO-TEK® silver epoxy. The use of an electrically conducting resin facilitates using the resin as electrical contacts to the interconnected nanostructures. This can be achieved by partially etching the encapsulating material in a subsequent step of the method, said etching performed using standard nanofabrication processes. The use of a transparent encapsulating material is advantageous, since it allows for subsequent stacking of layers (lamellas) to combine multiple layers of devices in a single stack.

### Cutting the Encapsulating Material

The fourth step of the method is cutting the encapsulating material in a direction that intersects at least two interconnected nanostructures, thereby manufacturing a transferable lamella comprising interconnected nanostructures. The cutting of the encapsulated material is thus carried out such that the cut lamella comprises interconnected nanostructures. Preferably, the cutting planes are selected such that the interconnection between the nanostructures are between said cutting planes.

The cut direction is preferably substantially parallel, such as parallel, to the substrate and/or substantially perpendicular, such as perpendicular, to either the growth direction of the elongated nanostructures or a direction along the axial length of the elongated nanostructures. The cutting step is illustrated in FIG. 1a (right). The encapsulating material may be cut by a microtome, such as a sledge microtome, a rotary microtome, a cryomicrotome, an ultramicrotome, a vibrating microtome, a saw microtome, or a laser microtome. Preferably, a microtome with a mounted diamond knife is used to cut the embedded nanostructures into very precise and thin sections, denoted herein as a lamellas.

### Transferable Lamellas

When the encapsulating material is cut, it results in a transferable lamella comprising interconnected nanostructures. Typically, the manufactured lamella is a thin, 3-dimensional layer, wherein the thickness of the lamella is much smaller than the other two dimensions (width and depth). The lamella thickness may be precisely controlled (preferably within a few nanometres) by the microtome settings. As an example, the lamella may have a thickness between 10 nm and 10 μm, such as between 50 nm and 5 μm. The cut side of the lamella (i.e. the side facing the substrate and defined by the width and depth) may preferably have a surface area of at least 10 mm², more preferably at least 1 cm², yet more preferably at least 25 cm². The cutting may be performed such that the transferable lamella(s) is ejected into a liquid bath, such as a water bath. Alternatively, dry cryo-microtomy may be used for transfer purposes. This process is carried out using liquid nitrogen as a cooling agent and the lamella is transferred directly onto a substrate without the need of a liquid bath.

Typically, the lamella comprises nanostructures that extend between two opposing surfaces of the lamella, most preferably two cut surfaces. As such, ends of the nanostructures, preferably each nanostructure, may be exposed at each of said opposing surfaces of the lamella, and the ends may be planar, as they are typically formed by cutting of the encapsulated superstructure.

It is, thus a preference that the nanostructures are not completely encapsulated by the encapsulating material following cutting. Instead, it is a preference that the nanostructures are embedded in the cutting material, such that at least one end, preferably two ends, of each nanostructure is exposed at surfaces of the lamella, preferably two opposing surfaces, e.g. two cut surfaces of the lamella.

Typically, the nanostructure has a cross section, in a plane parallel to the opposing surfaces, that has an aspect-ratio of 100 or below, such as wherein said cross-section is from 1 to 100, preferably wherein said aspect ratio is 10 or below, such as from 1 to 10, more preferably wherein said aspect ratio is 7 or below, such as from 1 to 7, even more preferably wherein said aspect ratio is 5 or below, such as from 1 to 5. The cross-section may further have a polygonal shape, such as hexagonal.

### Device Fabrication

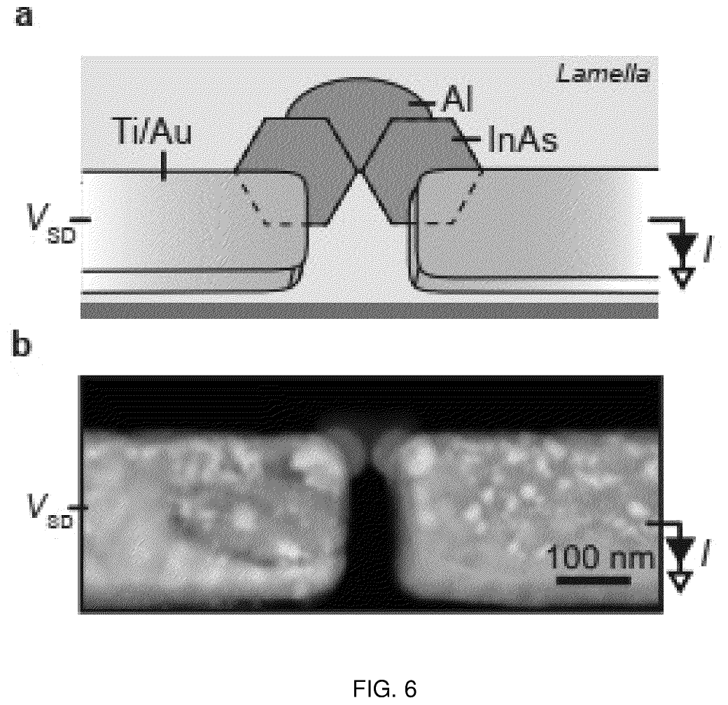

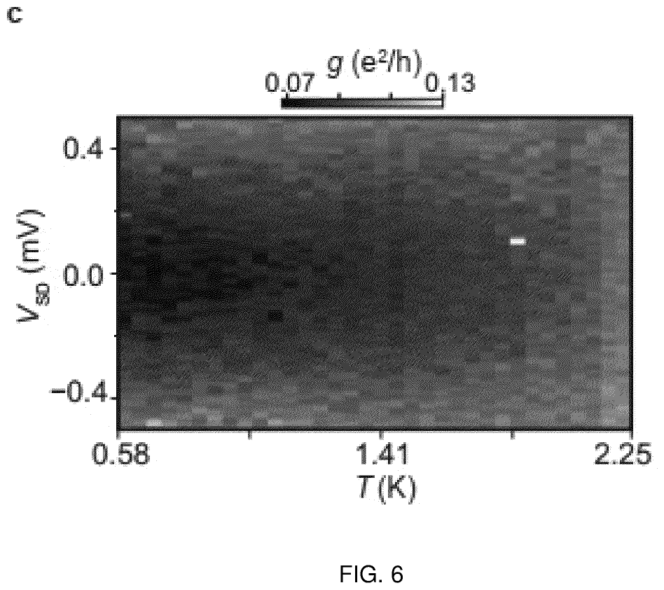

The lamella resulting from carrying out the method as disclosed herein, may preferably be transferred to any desired substrate. The lamella comprising the embedded nanostructures may be subject to further processing in order to realize many different electronic devices/components. As an example, metal contacts may be formed using standard nanofabrication techniques (such as electron beam lithography), said metal contacts contacting the interconnected nanostructures. The material of the contacts may be selected from the group of metals (e.g. gold, titanium, nickel, palladium, platinum), metal alloys, metalloids (e.g. germanium), superconducting materials, ferromagnetic materials, ferroelectric materials, and/or combinations thereof. An example of a device is shown in FIG. 6a, which shows an electronic device comprising two semiconducting InAs nanopillar segments that are contacted by Ti/Au metal contacts such that the device is configured to allow an electrical current to flow through the device. Accordingly, the disclosed method may further comprise the step of providing electrical contacts to at least two points of the interconnected nanostructured by lithography. Examples of lithography include atomic force microscopy lithography, ultraviolet (UV) lithography, deep ultraviolet (DUV) lithography, optical lithography, and electron beam lithography (EBL).

The disclosed method may further comprise the step of depositing a layer of a dielectric material, such as a high-κ dielectric, onto a cut side of the lamella, such that the dielectric layer at least partly covers the interconnected nanostructures. High-κ dielectrics are widely used in semiconductor manufacturing processes to form an insulator in metal-oxide-semiconductor field-effect transistors (MOSFETs), which are basic building blocks of modern electronics. The use of a high- dielectric in a MOSFET typically results in increased gate capacitance while minimizing associated leakage effects. The disclosed method may further comprise the step of providing a gate electrode by depositing a conductive material onto the dielectric layer, or by contacting the lamella with a gate substrate, such as a Si⁺⁺/SiO₂ substrate. Accordingly, the lamella as disclosed herein may comprise a dielectric layer, such as a high-κ dielectric layer, said layer at least partly covering the interconnected nanostructures. The lamella may further comprise a conductive material configured as a gate electrode, wherein said conductive material is provided on top of the dielectric layer to form a gate. The lamella may further comprise one or more electrical contacts of a material selected from the group of gold, titanium, nickel, germanium, palladium, platinum, palladium and combinations thereof and/or alloys thereof.

The present disclosure further relates to an electronic device comprising at least two interconnected nanostructures embedded in an encapsulating material, preferably wherein the nanostructures extend between the two opposing surfaces of the lamella, such as two cut surfaces, and/or wherein the cross section of any of the nanostructures, in a plane parallel to the opposing surface, has an aspect ratio below 100, such as below 10; and at least two metal contacts connected to the nanostructures. Typically, the lamella comprises nanostructures that extend between two opposing surfaces of the lamella, most preferably two cut surfaces. As such, ends of the nanostructures, preferably each nanostructure, may be exposed at each of said opposing surfaces of the lamella, and the ends may be planar, as they are typically formed by cutting of the encapsulated superstructure.

The nanostructures and the metal contacts form an electrical connection such that the device is configured to allow an electrical current to flow through the device from one metal contact to the other via the interconnected nanostructures. In one embodiment, the two nanostructures are electrically connected by a superconducting material configured to achieve a superconducting state at a critical temperature, such that a superconducting gap is formed in the device at or below said temperature. The superconducting material may be any material suitable for forming a superconductor (see list of exemplary superconducting materials elsewhere in the application). In particular, the use of aluminium as the superconducting material has shown to provide a conductance gap in an electronic device comprising two interconnected InAs nanopillar segments connected by aluminium. This is further explained in relation to FIG. 6a-6c. In one embodiment, the at least two interconnected nanostructures are InAs nanopillars.

In the following, various electronic devices/components manufactured using the presently disclosed method are described along with experimental results relating to the electrical properties of the devices/components.

As mentioned above, the lamella may typically comprise nanostructures that extend between two opposing surfaces of the lamella, most preferably between two cut surfaces, i.e. surfaces that have been cut in order to form one or more lamellas. As such, ends of the nanostructures may be exposed at each of said opposing surfaces of the lamella. The ends may thus be planar as they are typically formed by cutting of the encapsulated superstructure.

It is, thus a preference that the nanostructures are not completely encapsulated by the encapsulating material following cutting. Instead, it is a preference that the nanostructures are embedded in the cutting material, such that at least one end, preferably two ends, of each nanostructure is exposed at surfaces of the lamella, preferably two opposing surfaces, e.g. two cut surfaces of the lamella. The exposed ends of each nanostructure may thus be cut ends, located in the same plane as the opposing surfaces of the lamella.

Typically, the nanostructure has a cross section, in a plane parallel to the opposing surfaces, that has an aspect-ratio of 100 or below, such as wherein said cross-section is from 1 to 100, preferably wherein said aspect ratio is 10 or below, such as from 1 to 10, more preferably wherein said aspect ratio is 7 or below, such as from 1 to 7, even more preferably wherein said aspect ratio is 5 or below, such as from 1 to 5. The cross-section may further have a polygonal shape, such as hexagonal.

### Transistor Devices for Conventional Computing

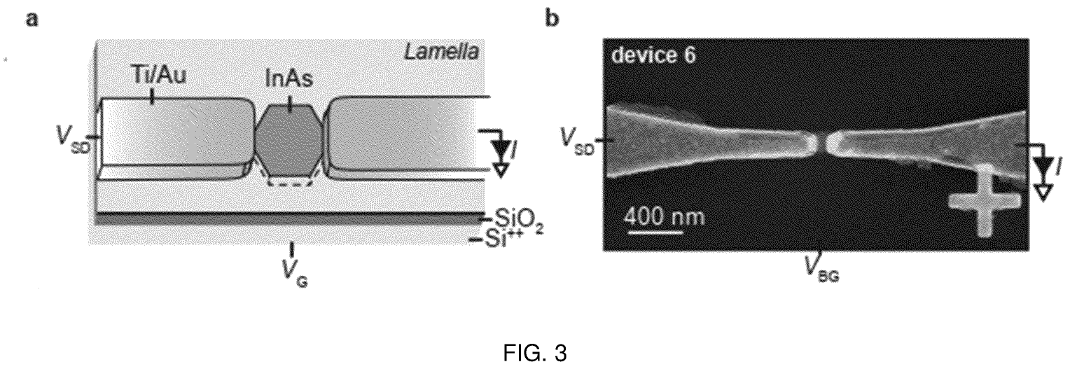

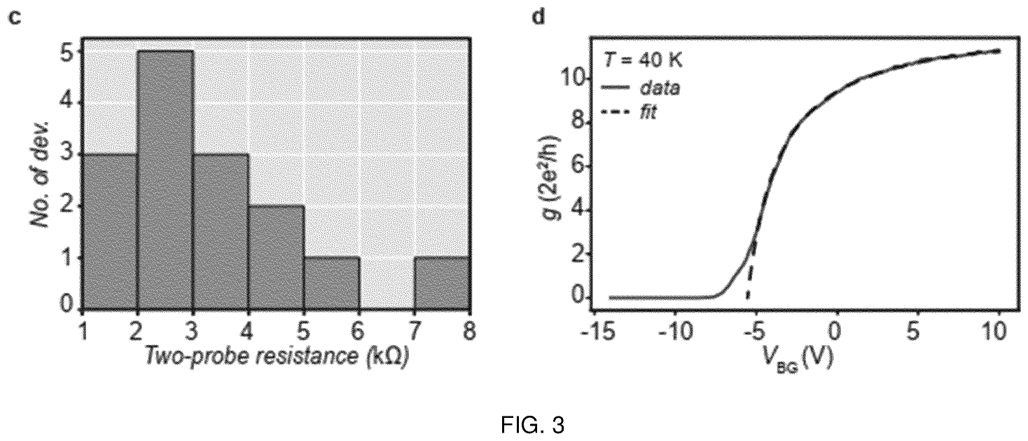

FIG. 3a shows a schematic of a MOSFET-like transistor fabricated based on InAs nanopillar cross-sections. A lamella comprising arrays of nanopillar cross-sections was transferred to a standard Si++/SiO₂ substrate before metallic leads were connected to the nanopillar cross-section via standard Electron beam Lithography (EBL) and clean room processes. The metallic leads allow an electric current to pass through the InAs nanopillar cross-section, wherein said current can be modulated by an external electrical field. The electric field is generated by applying a voltage to the underlying highly conducting Si++ slab, which is isolated from the device by an oxide (SiO₂). Accordingly, the setup comprises the basic architecture of a field effect transistor.

A histogram of the two-probe device resistances of a batch of 18 fabricated devices is shown in FIG. 3c. It was observed that 15 out of 18 devices conducted and exhibited room temperature resistances below 10 kΩ indicating that ohmic contacts can readily be produced. It was then investigated how well these devices behave as field-effect transistors (FETs), which is described in the following. FIG. 3d shows the conductance as a function of the voltage applied to the Si⁺⁺ slab (V_{BG}) at a temperature of T=40 K. By sweeping the backgate potential from a positive to a negative voltage, the conductance is brought from the saturation region (g˜10-12 2e²/h) through the linear region (g˜2-8 2e²/h) to a pinch off (g<0.2 2e²/h). The two first regions correspond to the device being ON and the last to the device being OFF. From this trace, the field effect mobility u can be estimated, which is a measure of how fast electrons move in a semiconductor when exposed to an electric field. This translates directly into how rapidly a transistor can be turned ON or OFF. The data was fitted to a commonly used expression for field effect transistors:

$$G ( {V}_{G} ) = {( {R}_{S} + \frac{{W}^{2}}{μ \cdot C ( {V}_{B G} - {V}_{t h} )} )}^{- 1}$$

where R_{S} is the series resistance, W is the width of the junction, C is the total capacitance of the channel to the gate electrode and Vₜₕ is the threshold voltage. From the fit, the field effect mobility of this device was estimated to be on the order of several 1000 cm²/V·s, which is comparable to other InAs-based FETs. To obtain a more precise quantitative measure of the mobility, a thorough estimate of the capacitances of each individual device has to be made. However, the behaviour of the conductance of the device in response to an applied electrical field looks similar to a standard FET. A crucial advantage of this type of device over regular FETs is its ability to be transferred in large arrays onto any desired substrate. The method as disclosed herein can be utilized to stack such devices into vertical architectures for space optimization, tandem devices or minimizing pitch of light-emitting diodes (described in more detail elsewhere in this application).

### Quantum Effects in Nanostructures

The following example is based on the same transistor geometry as described in relation to FIG. 3. However, this example investigates quantum effects that appear in such devices as the temperature is brought below 3 K.

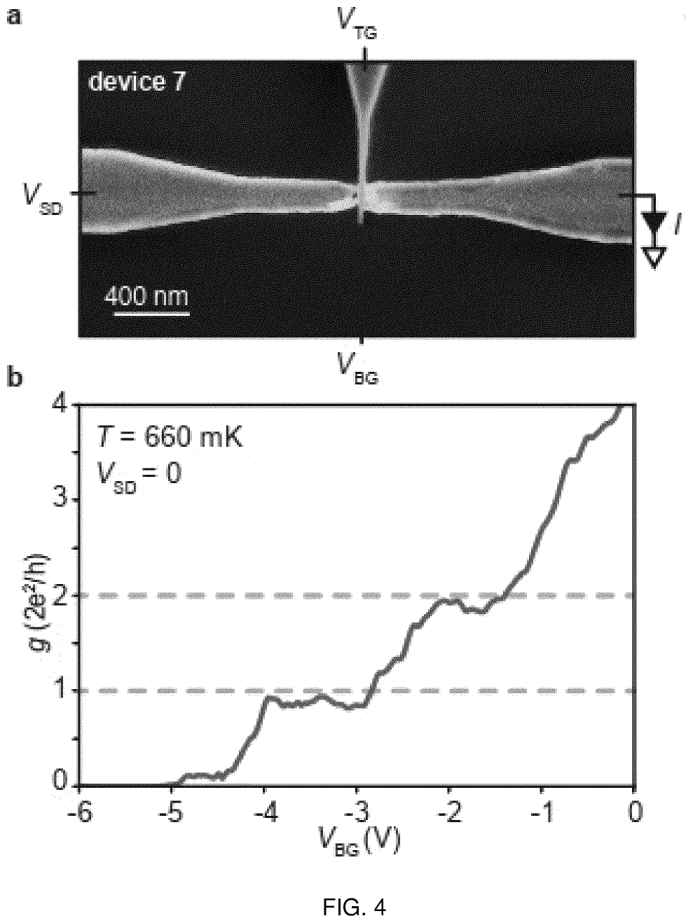

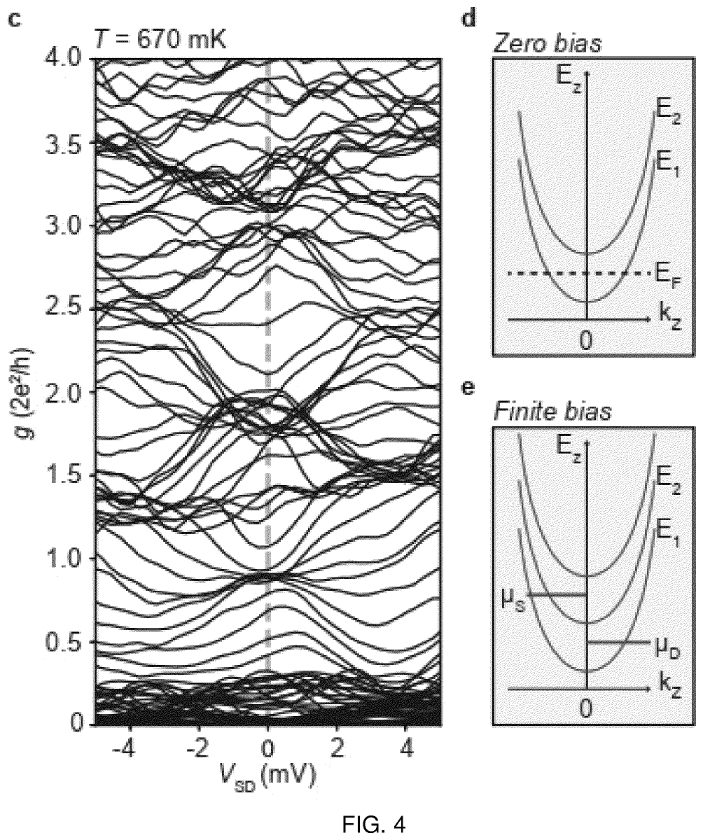

FIG. 4a shows an SEM image of one of the electronic devices according to the present disclosure. The device was characterized using the same setup as described earlier. FIG. 4b shows the zero-bias conductance as a function of backgate potential. From this graph, it can be observed that as the gate potential is swept, the conductance plateaus at the two first integer values of the quantum of conductance (g₀=2e²/h). This indicates that the transistor device has changed into a quantum point contact, which implies that the mean free path (the length at which the carriers experience no scattering) is now similar to or larger than the device length. Additionally, it suggests that the temperature is lowered sufficiently to yield an energy resolution, allowing the first few transverse modes in the conduction channel to be observed. As the gate is swept, the Fermi energy (E_{F}) is modulated such that the individual modes in the semiconductor become energetically accessible one by one, resulting in a plateauing effect in conductance at units of g₀. In order to verify the origin of the plateaus, waterfall plots of differential conductance as a function of source-drain bias and backgate voltage is shown in FIG. 4c. Along V_{BG}=0 (grey dashed line) a bunching effect of the individual traces at the first 3 integer values of g₀ can be observed.

Additionally, at finite bias, and most pronounced around V_{SD}=±4, a similar bunching effect at half-integer values can be observed. The bunching effect at integer values of g₀ can be understood from the same zero-bias picture already given in relation to FIG. 4b. The half-integer conductance bunching corresponds to a source-drain bias configuration where only right (left) moving carriers from the source (drain) electrode are provided energy to reach the next mode and only contribute with half a conductance quantum. In FIGS. 4d and 4c the zero-bias case and finite bias case are illustrated, respectively. Half-integer plateaus are typically observed only in clean samples since a large bias usually results in increased noise or pronounced conductance dynamics due to self-gating effects. Potential applications of such quantum point contact devices cover ultra precise charge detectors as read-out devices for e.g. quantum bits.

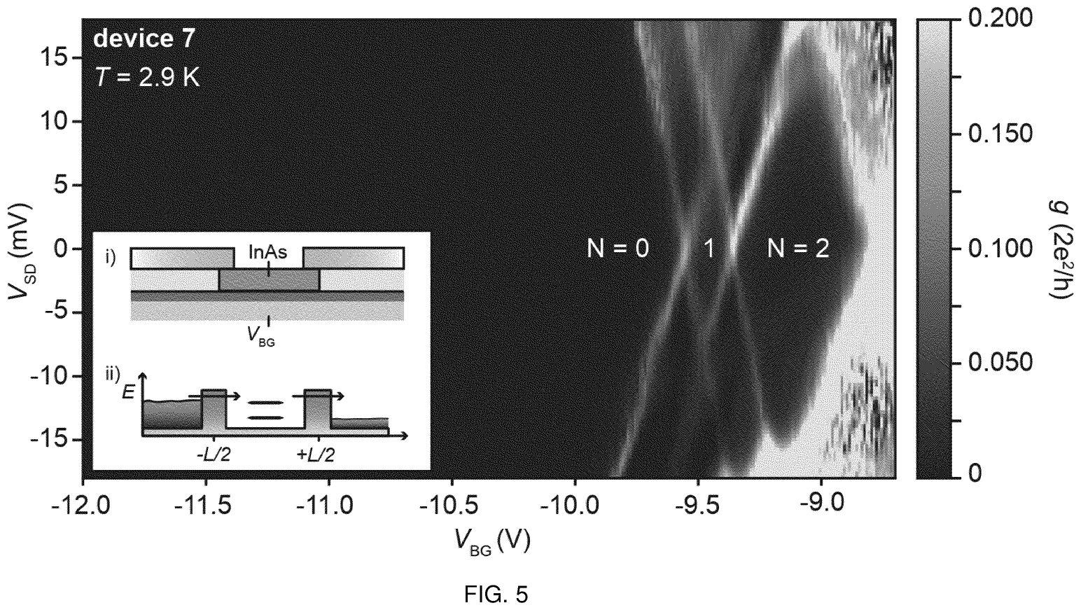

The following paragraph describes measurements of the same device as presented in relation to FIG. 4, however, for these measurements the device was brought into the tunnelling regime (g<<g₀) by applying large negative voltages on the backgate. FIG. 5 shows a colour map of the differential conductance as a function of source-drain bias and backgate voltage. Diamond-shaped structures can be observed, which are signatures of electron transport through a quantum dot (QD) brought into the Coulomb blockade regime. The dark areas of the plot correspond to zero conductance, i.e. a situation wherein the current across the device is blocked. Close to the source and drain contacts in semiconductor devices, the electric field lines typically terminate at the metal electrodes rather than in the semiconductor. This can lead to a reduction of carriers close to the metal electrodes effectively creating a set of barriers, as schematically shown in the inset of FIG. 5. A number of interesting properties can be inferred from the shape of the diamond, such as the charging energy (E_{C}=7.2 meV), the gate capacitance (C_{g}=0.9 aF), the lever arm (αₐᵣₘ=0.03) and the total capacitance of the device (Cₜₒₜ=22 aF). These values correspond closely to InAs quantum dots of similar size grown by self-assembly.

An advantage of the presently disclosed method, over e.g. self-assembled QDs or QDs defined in standard nanowires, is the ability of the method to produce and transfer nanostructures (such as quantum dots) in large predefined arrays with growth conditions that are optimized for dimensionality, desired bandgap, strain and pitch. The high level of control makes the presently disclosed method highly relevant for quantum based applications in general, e.g. large-scale production of single photon sources.

### Hybrid Materials for Quantum Computing

The following paragraph describes hybrid materials for quantum computing, in particular semiconductor/superconductor hybrids. The presently disclosed method can be utilized to produce the device architecture for quantum transport applications such as Josephson junctions and semiconductor/superconductor hybrids in a highly scalable way. A schematic and an SEM image of an electronic device according to the present disclosure is shown in FIG. 6a and FIG. 6b, respectively. The device comprises two semiconducting InAs nanopillar segments electrically connected to a second material (here aluminium). The InAs/Al hybrid material is embedded in a resin and connected by two metallic contacts.

FIG. 6c shows a color map of differential conductance (g) measured as of function of the source-drain bias, V_{SD}, and the temperature, T. A suppressed conductance within V_{SD}˜±200 μV at T˜600 mK can be observed, which disappears gradually as the temperature is increased to 2.25 K. This trend is in good agreement with superconductivity being destroyed as the temperature is swept across the critical temperature of Al (T_{C}˜1.2 K), indicating that a superconducting state is formed in the semiconductor due to the proximity of the superconducting Al. Additionally, a superconducting gap of this magnitude is consistent with experiments probing the induced superconductivity of Al in InAs nanopillars. Coulomb charging effects could possibly emulate a similar behaviour but that large gate sweeps performed in the same gate range at constant temperature (T=300 mK) show no Coulomb resonances. This effect is, so far, only observed in so-called hybrid materials, which many research groups investigate as a fundamental unit for realising quantum computation. By embedding multiple of these units in a lamella and using standard EBL techniques well-known to industry, the presently disclosed method can serve as a highly scalable infrastructure for production of quantum (or regular) transistors independent of substrate. This specifically concerns applications in topological quantum computing and gatemon based superconducting qubits, where existing techniques are either substrate dependent or focus on single structures not suitable for large scale production.

### Three-Dimensional Architectures

The presently disclosed method allows for stacking of multiple lamellas. This paragraph provides a few examples of potential applications. Multiple layers of devices can be combined by stacking lamellas on top of each other as seen in FIG. 7. For instance, light emitting diodes of different wavelength (colour) can be stacked to form red, green and blue (RGB) pixels. For this application, the lamellas need to be optically transparent. Preferably, light emitting diodes of the same wavelength are provided in the same lamella such that a first lamella comprises LEDs configured to emit red, a second lamella comprises LEDs configured to emit green, etc. When stacked on top of each other, the lamellas can be aligned to form pixel units, each pixel unit comprising three pixels (red, green and blue). An advantage of such a stack is that the individual pixel sizes and the pixel pitches can be reduced beyond the current commercial state-of-the art. In addition, the disclosed method facilitates the use of different diode materials in the different lamellas, each diode material optimized for a specific colour (e.g. InGaN for emitting blue). The stacks of lamellas could be used to realise high-efficiency solar cells known as tandem solar cells. For this application, p-n junction materials with various bandgaps may be embedded in the different lamellas to harvest different wavelengths of the solar radiation (e.g. infra-red, visible and UV). Another advantage of the stacking technique is that it can be used to pack devices in a vertical approach for higher device densities.

### DETAILED DESCRIPTION OF DRAWINGS

The invention will in the following be described in greater detail with reference to the accompanying drawings. The drawings are exemplary and are intended to illustrate some of the features of the presently disclosed invention, and are not to be construed as limiting to the presently disclosed invention.

### Example 1—Growth and Embedding of Nanostructures

FIG. 1a (left) shows a schematic of a predefined array of semiconducting nanopillars grown from a substrate. The height and diameter of the nanopillars can be controllably and reproducibly engineered. FIG. 1a (right) shows the plurality of semiconducting nanopillars embedded in an insulating encapsulating material. In this embodiment, the encapsulating material is an optically transparent resin. A thin section (lamella) parallel to the substrate has been cut from the encapsulating material, said section comprising a plurality of nanopillar sections. The lamella can be cut using a microtome-setup configured to precisely control the lamella thickness, preferably with a precision of a few nanometers. The properties, e.g. the electrical properties, of the individual nanopillar sections are preferably identical within a lamella.

### Example 2—Array of Nanopillar Sections

FIG. 1b (left) shows a TEM image of a lamella comprising an ordered array of cross-sections of nanopillars embedded in an encapsulating material. FIG. 1b (right) shows a TEM image of an individual cross-section of a nanopillar of the array shown to the left. In this embodiment, a layer of Al has been deposited directionally on one side of the nanopillar segment (visible on the right side of the nanopillar segment).

### Example 3—Merged Nanopillars

FIG. 2a shows an SEM image of a plurality of nanopillars (e.g. InAs nanopillars) in close proximity to each other, wherein some of the nanopillars have merged together during growth. The merging can be well controlled by adjusting a number of parameters related to the growth, such as growth time, substrate temperature, and material fluxes. The nanopillars were grown using a vapour-liquid-solid (VLS) growth technique.

FIG. 2b shows an SEM image of four nanopillars (e.g. InAs nanopillars), wherein three of the nanopillars have merged together during growth.

### Example 4—Embedded Merged Nanopillars

FIG. 2c shows a schematic of three merged nanopillars embedded in an encapsulating material such as an epoxy-based resin.

### Example 5—Embedded Core-Shell Nanopillars

FIG. 2d shows a schematic of three nanopillars embedded in an encapsulating material, wherein the nanopillars are conductively interconnected through a first layer provided around the core of the nanopillars. The structure comprises two different materials: a core material and a first layer material. It is possible to obtain a horizontal p-n junction by appropriate choice of materials for the core and first layer of the nanopillars.

### Example 6—TEM Image of Merged Nanopillars

FIG. 2e shows a TEM image of three merged nanopillars, wherein the nanopillars merged during growth, and wherein aluminium (Al) has been directionally deposited on one side of the interconnected nanostructures. The image corresponds roughly to the schematic shown in FIG. 2c.

### Example 7—Device Comprising Six Interconnected Nanopillar Segments

FIG. 2f shows a schematic of an electronic device comprising six interconnected nanopillar segments (cross-sections), wherein the nanopillars merged during the growth step. The superstructure is contacted by two metallic leads before a dielectric is grown on the sample in order to isolate the later deposited metal gates. The metal gates are used to apply external electrical fields that control the electrochemical potential of the underlying semiconductor locally.

### Example 8—Transistor Device

FIG. 3a shows a schematic of an electronic device comprising an InAs nanopillar cross-section and two metal contacts (e.g. Ti/Au leads). The device was fabricated by transferring a lamella comprising an array of nanopillar cross-sections to a standard Si⁺⁺/SiO₂ substrate, i.e. a substrate comprising a slab of highly conducting Si⁺⁺ and an insulating SiO₂ layer. Then, metallic contacts were connected to one of the nano-pillar cross-sections using standard EBL and clean room processes. The electronic device is configured to allow an electric current to pass from one metal contact (e.g. the source) through the InAs nanopillar cross-section to the other metal contact (e.g. the drain), wherein the electric current can be modulated by an external electric field. The electric field is generated by applying a voltage to the Si⁺⁺ slab, which is isolated from the remaining device (nano-pillar cross-section and metal contacts) by the insulating layer made of SiO₂. Accordingly, the electronic device constitutes a field effect transistor.

FIG. 3b shows an SEM image of the electronic device described in relation to FIG. 3a.

### Example 9—Experimental Data of a Transistor Device

FIG. 3c shows a histogram of the two-probe resistance of a batch of 18 fabricated electronic devices similar to the one shown schematically in FIG. 3a and imaged using an SEM on FIG. 3b. It was observed that 15 out of 18 devices exhibited room temperature resistances below 10 kΩ, which suggested that the devices behaved as ohmic contacts at room temperature. The histogram only contains data from these 15 devices.

FIG. 3d shows a graph with data from a characteristic of one of the electronic devices described in relation to FIG. 3a-3c. The graph shows the conductance (in units of quantum of conductance) as a function of the applied backgate voltage, V_{BG}. In this example, V_{BG} was applied to the Si⁺⁺ slab at a temperature of 40 K. By sweeping the backgate potential from a positive to a negative voltage, the conductance was brought from the saturation region (g˜10-12 2e²/h) through the linear region (g˜2-8 2e²/h) to a pinch off (g<0.2 2e²/h). The first two regions correspond to the device being ON and the last region corresponds to the device being OFF. The data was fitted to a commonly used expression for field effect transistors. The field effect mobility μ can be estimated from the fit (dashed line) to the data.

### Example 10—Quantum Effects in an InAs Transistor Device

FIG. 4a shows an SEM image of an electronic device similar to the device shown in FIG. 3b and described in relation to FIG. 3a. The electrical properties of the device were investigated using a similar experimental setup as described in relation to FIG. 3a, however at a much lower temperature.

FIG. 4b shows a graph with data from an experiment wherein the electrical properties of one of the electronic devices were studied at low temperature (660 mK). At such a low temperature, the device exhibits quantum effects. The graph shows the differential conductance (in units of 2e²/h) versus the applied backgate potential, V_{BG} (units of V). From the graph it can be observed that as V_{BG} is swept, the conductance plateaus at the two first integer values of the quantum of conductance, 2e²/h. This indicates that the electronic device behaves like a quantum point contact, which implies that the mean free path is similar to or larger than the device length. Additionally, it suggests that the temperature was low enough to observe the first few transverse modes in the conduction channel. As the backgate potential is swept, the Fermi energy (E_{F}) is modulated such that the individual modes in the semiconductor become energetically accessible one by one, resulting in a plateauing effect in conductance at units of g₀ (2e²/h).

FIG. 4c shows waterfall plots of differential conductance as a function of the source-drain bias, V_{SD} (mV), and backgate voltage, in order to verify the origin of the plateaus. A bunching effect of the individual traces can be observed at the first three integer values of g₀ along V_{BG}=0 (grey dashed line). Additionally, at finite bias, and most pronounced around V_{SD}=±4, a similar bunching effect at half-integer values can be observed. The bunching effect at integer values of g₀ can be understood from the same zero-bias picture already given in relation to FIG. 4b. The half-integer conductance bunching corresponds to a source-drain bias configuration where only right (left) moving carriers from the source (drain) electrode are provided energy to reach the next mode and only contribute with half a conductance quantum.

FIG. 4d and FIG. 4e show schematics of the zero-bias and finite-bias case, respectively. Half-integer plateaus are typically observed only in clean samples since a large bias usually results in increased noise or pronounced conductance dynamics due to self-gating effects. Potential applications of such quantum point contact devices cover ultra precise charge detectors as read-out devices for e.g. quantum bits.

### Example 11—Quantum Dots in InAs Nanopillar Segment Devices

FIG. 5 shows a colour map of the differential conductance as a function of source-drain bias and backgate voltage. From the plot, diamond-shaped structures can be observed, which are signatures of electron transport through a quantum dot (QD) brought into the Coulomb blockade regime, where the current across the device is blocked in the dark areas. Close to the source and drain contacts in semiconductor devices, the electric field lines typically terminate at the metal electrodes rather than in the semiconductor. This can lead to a reduction of carriers close to the metal electrodes, effectively creating a set of barriers as schematically shown in the inset of FIG. 5. From the shape of the diamond(s), values for the charging energy (E_{C}=7.2 meV), the gate capacitance (C_{g}=0.9 aF), the lever arm (αₐᵣₘ=0.03) and the total capacitance of the device (Cₜₒₜ=22 aF) can be estimated. Said values correspond closely to InAs QDs of similar size grown by self-assembly.

### Example 12—Semiconductor/Superconductor Hybrid Device

FIG. 6a shows a schematic of an electronic device comprising two semiconducting InAs nanopillar cross-sections that are interconnected and embedded in a lamella. The two nanopillar cross-sections are electrically connected by an aluminum layer, which was in-situ grown. The device further comprises two metallic contacts (e.g. Ti/Au leads), each in contact with one of the two nanopillar cross-sections as shown on the schematic, such that a current may flow through the device from one metal contact (e.g. denoted the source) to the other metal contact (e.g. denoted the drain).

FIG. 6b shows an SEM image of an electronic device similar to the one in FIG. 6a. The electronic device was fabricated using standard EBL processing. The aluminum layer is present in the device, but it is not visible on the SEM image due to lack of contrast.

### Example 13—Superconducting Gap in an InAs/Al Transistor Device

FIG. 6c shows a color map of differential conductance (g) measured as of function of V_{SD} and T. A suppressed conductance within V_{SD}˜±0.2 mV at T˜0.6 K can be observed, which disappears gradually as the temperature is increased to 2.25 K. This phenomenon can be explained by the superconductivity vanishing as the temperature is swept across the critical temperature of Al (T_{C}˜1.2 K), indicating that a superconducting state is formed in the semiconductor due to the proximity of the superconducting Al. Additionally, a superconducting gap of this magnitude is consistent with experiments probing the induced superconductivity of Al in InAs nano-pillars. Coulomb charging effects could emulate a similar behavior, but large gate sweeps performed in the same gate range at constant temperature (T=300 mK) show no Coulomb resonances.

### Example 14—Stacking of Lamellas

FIG. 7a shows a schematic of a stack of multiple lamellas (here exemplified with three lamellas) imaged from above. In this example, the lamellas are optically transparent, which ensures that multiple layers of devices can be combined on top of each other to form a stack, which has several applications. For example, light emitting diodes of different wavelengths can be stacked to form red, green and blue (RGB) pixels. This stacking technique ensures that the individual light emitting diodes are packed more closely, thereby reducing the individual pixel sizes and pixel pitches beyond the current commercial state-of-the art. In addition, the method as disclosed herein facilitates the use of different diode materials in the different lamellas, wherein each diode material is optimized for a specific colour (e.g. InGaN for emitting blue). As an example, the individual diode distances of one pixel unit could be approximately 100 nm and the distance between adjacent pixel units could be approximately 10 μm or less.

FIG. 7b shows a side-view schematic of the stack of lamellas shown in FIG. 7a.

### Example 15—Hybrid Nanostructures/Heterostructures

FIGS. 8-16 show a variety of examples of hybrid nanostructures according to the present disclosure, i.e. nanostructures comprising at least two different materials, typically a semiconductor and a superconductor. In most preferred embodiments, the elongated nanostructures are grown such that at least two of said nanostructures are conductively interconnected at least partially along their growth direction (FIGS. 9-12 and FIGS. 14-16). In other embodiments, at least a first layer is grown or deposited to conductively interconnect at least a part of the elongated nanostructures (FIG. 8 and FIG. 13). Some embodiments feature both a first layer and a second layer (FIGS. 12-15).

FIG. 8 shows a schematic of three interconnected nanostructures according to the present disclosure. In this embodiment, the nanostructures are interconnected by a first layer surrounding the core of the nanostructures. In this example, the first layer is formed from an electrically conducting material, e.g. a superconducting material, a metal, a semiconductor, or a ferromagnetic material.

FIG. 9 shows a schematic of three interconnected nanostructures according to the present disclosure. In this embodiment, the nanostructures are interconnected through the core of the nanostructures, i.e. the elongated nanostructures are grown such that the nanostructures are conductively interconnected. A first layer has been grown or deposited on the outside of the three merged nanostructures, said first layer fully surrounding the interconnected nanostructures. As an example, the core may be a semiconductor and the first layer may be a superconductor, whereby a semiconductor/superconductor hybrid is formed.

FIG. 10 shows a schematic of a heterostructure according to the present disclosure that is largely similar to the embodiment shown in FIG. 9. However, in this example the first layer is provided as an insulator, i.e. formed in an insulating material. Electrical contacts have been provided, said contacts forming an electrical connection to the interconnected nanostructures. In this example, the electrical contacts are formed in-situ and the first layer is deposited subsequently, e.g. by atomic layer deposition.

FIG. 11 shows a schematic of a heterostructure according to the present disclosure that is largely similar to the embodiment shown in FIG. 10. Here, electrical gates have been provided to the heterostructure.

FIG. 12 shows a schematic of three interconnected nanostructures according to the present disclosure, wherein a first layer has been grown or deposited on the outside of said nanostructures, said first layer fully surrounding the nanostructures, and wherein a second layer has been grown or deposited on the outside of the first layer. In this example, the first layer may be any material described herein (e.g. semiconductors, superconductors, ferromagnetic materials, ferroelectric materials, and piezoelectric materials), and the second layer is preferably an insulator. The structure has been provided with electrical gates.

FIG. 13 shows a schematic of a heterostructure according to the present disclosure that is largely similar to the embodiment shown in FIG. 12, with the exception that the three nanostructure cores have not merged during growth. Instead, the nanostructures are conductively interconnected by a first layer, which is grown or deposited on the outside of the nanostructures.

FIG. 14 shows an example of a heterostructure according to the present disclosure, which comprises three merged nanostructures (merged during growth), wherein a first layer has been grown or deposited to conductively interconnect at least a part of the elongated nanostructures (here approximately half of the interconnected structure). A second layer has been provided on the outside of the first layer and the core of the nanostructures, said second layer fully surrounding the interconnected nanostructures. In this example, the second layer is an insulator. The structure has been provided with electrical gates. In this embodiment, the electrical gates are grown in-situ.

FIG. 15 shows an example of a heterostructure largely similar to the one shown in FIG. 14. However, in this embodiment, electrical contacts have been provided at the two ends of the interconnected nanostructures, said electrical contacts preferably formed in-situ.

FIG. 16 shows an example of a heterostructure according to the present disclosure, which comprises three merged nanostructures (merged during growth), wherein a first layer has been grown or deposited to insulate the interconnected nanostructures. In this example, the first layer is a high-κ dielectric. The structure has been provided with electrical contacts, e.g. formed in-situ. Hence, in this example the electrical contacts are formed prior to the formation of the first layer.

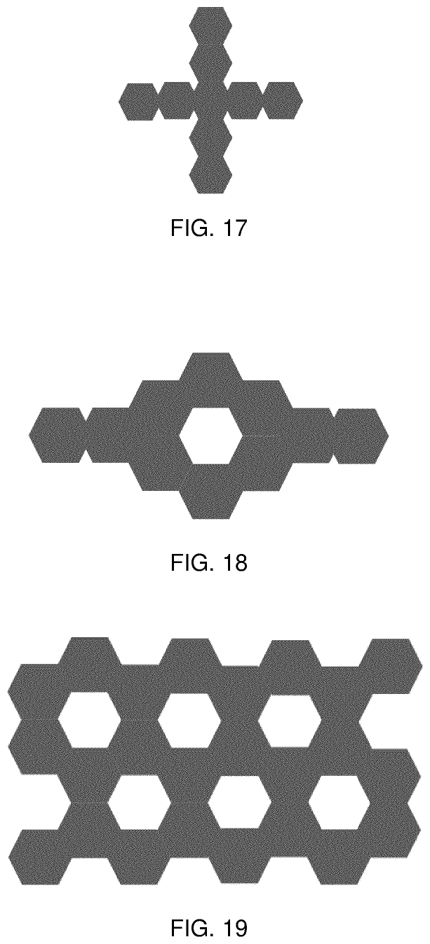

FIG. 17 shows an example of a more advanced network of interconnected nanostructures that are merged to form a cross.

FIG. 18 shows an example of a more advanced network of interconnected nanostructures that are merged to form a ring-like structure with an opening.

FIG. 19 shows an example of a more advanced network of interconnected nanostructures that are merged to form a meta-material comprising several openings.

### REFERENCE NUMERALS

10. Nanostructure (core)
11. First layer
12. Second layer
13. Electrical contacts
14. Electrical gate

### FURTHER DETAILS OF THE INVENTION

1. A method of manufacturing a transferable lamella comprising interconnected nanostructures, the method comprising the steps of:
a) providing a substrate such as a planar substrate;
b) forming at least one superstructure on the substrate, said superstructure comprising a plurality of elongated nanostructures (e.g. formed by growth, deposition, and/or etching); wherein
   the elongated nanostructures are formed such that at least two of said nanostructures are conductively interconnected, and/or
   wherein at least a first layer is grown or deposited to conductively interconnect or insulate at least a part of the elongated nanostructures;
   optionally providing additional layers by growth or deposition on the outside of the first layer and/or on the outside of the elongated nanostructures;
c) encapsulating at least a portion of said superstructure in an encapsulating material, said portion comprising at least two interconnected nanostructures; and
d) cutting the encapsulated superstructure in a direction that intersects at least two interconnected nanostructures, thereby manufacturing a transferable lamella comprising interconnected nanostructures.

2. The method according to item 1, wherein the superstructure is formed by growing a plurality of elongated nanostructures from the substrate.

3. The method according to item 2, wherein at least two of said elongated nanostructures are conductively interconnected at least partially along their growth direction.

4. The method according to any one of the items 2-3, wherein the growth direction of the elongated nanostructures is substantially perpendicular to the substrate.

5. The method according to any one of the items 2-4, wherein the elongated nanostructures are grown from an angled ridge on the substrate.

6. The method according to item 1, wherein the elongated nanostructures are formed by anisotropic etching such as deep reactive-ion etching.

7. The method according to any one of the preceding items, wherein at least a first layer is grown or deposited to conductively interconnect or insulate at least a part of the elongated nanostructures as part of step b).

8. The method according to item 7, wherein the first layer is directionally deposited on one side of the nanostructures.

9. The method according to any of the items 7-8, wherein a second layer is grown or deposited on the outside of the first layer to insulate the interconnected nanostructures.

10. The method according to item 9, wherein the second layer is an insulator.

11. The method according to any of the preceding items, wherein the elongated nanostructures are grown from the substrate, wherein a conductive interconnection between the elongated nanostructures is formed by merging of said nanostructures during growth.

12. The method according to item 11, wherein an overlap between two interconnected nanostructures in a plane parallel to the substrate, is between 1 nm and 1 μm, preferably between 1 nm and 0.5 μm.

13. The method according to any one of the preceding items, wherein the first layer comprises a material selected from the group of semiconductors, superconductors, ferromagnetic materials, ferroelectric materials, ferromagnetic insulators, insulators, and piezoelectric materials.

14. The method according to any one of the preceding items, wherein the encapsulating material is selected from the group of: poly(methylmethacrylate), polystyrene, polycarbonate, epoxy-based resins such as Epon and Durcupan, low-density polyethylene, SU8, SPURR, PDMS and/or conductive resins.

15. The method according to any one of the preceding items, wherein the encapsulating material has a Young's modulus of at least 1500 MPa.

16. The method according to any one of the preceding items, wherein the encapsulating material is electrically insulating with a resistivity of at least 10⁷ Ω·m and/or wherein the encapsulating material is transparent to visible light.

17. The method according to any one of the preceding items, wherein the encapsulating material is cut by a microtome, such as a sledge microtome, a rotary microtome, a cryomicrotome, an ultramicrotome, a vibrating microtome, a saw microtome, and/or a laser microtome.

18. The method according to any one of the preceding items, wherein the cutting is configured such that cut lamellas are ejected onto a liquid bath, such as a water bath.

19. The method according to any one of the preceding items, wherein the encapsulated material is cut to form a lamella with a thickness between 10 nm and 10 μm, such as between 50 nm and 5 μm.

20. The method according to any one of the preceding items, wherein a cut side of the lamella has a surface area of at least 10 mm² more preferably at least 1 cm², yet more preferably at least 25 cm².

21. The method according to any one of the preceding items, further comprising a step of depositing a layer in a dielectric material, such as a high-κ dielectric, onto a cut side of the lamella, such that the dielectric layer at least partly covers the interconnected nanostructures.

22. The method according to any one of the preceding items, further comprising providing a gate electrode by depositing a conductive material onto a dielectric layer that covers at least a part of the nanostructures, or by contacting the lamella with a gate substrate, such as a Si⁺⁺/SiO₂ substrate.

23. The method according to any one of the preceding items, further comprising providing electrical contacts to at least two points of the interconnected nanostructured by lithography, such as by electron beam lithography.

24. The method according to any one of the preceding items, wherein the material of the contacts is selected from the group of metals (e.g. gold, titanium, nickel, palladium, platinum), metal alloys, metalloids (e.g. germanium), superconducting materials, ferromagnetic materials, ferroelectric materials, and/or combinations thereof.

25. The method according to any one of the preceding items, wherein the elongated nanostructures are grown such that the interconnected nanostructures form at least one p-n junction in the plane of the lamella.

26. The method according to any of the preceding items, wherein the substrate is a III/V substrate (e.g. InAs, GaAs, GaN, GaSb, or InP), or wherein the substrate is a IV substrate (e.g. Si, Ge, or SiGe).

27. The method according to any one of the preceding items, wherein the elongated nanostructures are crystalline semiconductor nanostructures.

28. The method according to any one of the preceding items, wherein the superstructure comprises elongated nanostructures of a crystalline semiconductor and at least a first layer of a superconducting material.

29. The method according to any one of the preceding items, wherein the superstructure comprises:
elongated nanostructures of a crystalline semiconductor material, and
at least a first layer of a superconducting material,
   wherein an interface is formed between the semiconductor material and the first layer in order to provide a superconducting gap in the superstructure.

30. The method according to item 28, wherein an interface formed between the semiconductor nanostructure and the at least first layer is configured to induce a superconducting gap in the semiconductor nanostructure.

31. The method according to any one of the preceding items, wherein the superstructure comprises:
a plurality of elongated nanostructures of a semiconductor material, and
at least a first layer selected from the group of superconducting materials, ferromagnetic materials, and/or insulators.

32. The method according to item 31, wherein the first layer comprises a superconducting material, and wherein the superstructure comprises an interface between the semiconductor material and the first layer, said interface configured to provide a superconducting gap.

33. The method according to any one of the preceding items, wherein the elongated nanostructures are semiconductor nanostructures provided in a semiconducting material selected from the collection of group III-V combinations, such as InAs, InP, InSb, GaAs, GaSb, AlSb and InGaAs, or group IV elements such as Si or Ge, or group IV combinations such as SiGe, or group II-VI combinations such as ZnO, ZnSe and CdSe, or group I-VII combinations.

34. The method according to any one of the preceding items, wherein at least one of the elongated nanostructures is a heterostructure, such as a radial heterostructure.

35. The method according to any one of the preceding items, wherein the elongated nanostructures comprise a semiconductor material and a first layer selected from the group of superconducting materials, ferromagnetic materials, and/or insulators.

36. The method according to any one of the preceding items, wherein the elongated nanostructures comprise an insulating core and a first layer selected from the group of semiconductors, superconducting materials, and/or ferromagnetic materials.

37. The method according to any one of the preceding items, wherein the elongated nanostructures comprise a semiconductor material and a first layer selected from the group of semiconductors, ferromagnetic insulators and piezoelectric materials.

38. A transferable lamella comprising interconnected nanostructures embedded in an encapsulating material.

39. The lamella according to item 38, wherein said nanostructures are electrically interconnected.

40. The lamella according to any one of items 38-39, wherein the nanostructures comprise multiple semiconductor nanocrystals provided in a semiconducting material selected from the collection of group III-V combinations, such as InAs, InP, InSb, GaAs, GaSb, AlSb and InGaAs, or group IV elements such as Si or Ge, or group IV combinations such as SiGe, or group II-VI combinations such as ZnO, ZnSe and CdSe, or group I-VII combinations.

41. The lamella according to any one of items 38-40, wherein the nanostructures are interconnected by a superconducting material.

42. The lamella according to any one of items 38-41, wherein the thickness of the lamella is between 10 nm and 10 μm, such as between 50 nm and 5 μm.

43. The lamella according to any one of items 38-42, wherein a cut side of the lamella has a surface area of at least 10 mm² more preferably at least 1 cm², yet more preferably at least 25 cm².

44. The lamella according to any one of items 38-43, wherein at least a part of the interconnected nanostructures is covered by a dielectric material, such as a high-κ dielectric.

45. The lamella according to any one of items 38-44, wherein the lamella comprises a gate electrode in the form of a conductive material onto a dielectric layer that covers at least a part of the nanostructures.

46. The lamella according to any one of items 38-45, wherein the lamella comprises at least two electrical contacts, each forming an electrical connection to the interconnected nanostructures.

47. The lamella according to any one of items 38-46, wherein the materials of the interconnected nanostructures are selected to form a p-n junction.

48. A stack comprising a plurality of transferable lamellas according to any one of items 38-47.

49. The stack according to item 48, wherein the stack comprises one or more pixel units, each pixel unit comprising one or more light emitting diodes (LEDs) embedded in the lamellas.

50. The stack according to item 49, wherein the stack comprises:
a first lamella comprising one or more first LEDs configured to emit light of a first wavelength (e.g. red);
a second lamella comprising one or more second LEDs configured to emit light of a second wavelength (e.g. green); and
a third lamella comprising one or more third LEDs configured to emit light of a third wavelength (e.g. blue),
   wherein the first, the second and the third lamella are stacked on top of each other and aligned such that the one or more first, second and third LED(s) form one or more pixel unit(s).

51. A superstructure circuit, comprising:
at least one lamella comprising multiple interconnected nanostructures;
at least two contacts in a conductive material, configured to form an electrical connection to points of the interconnected nanostructures of the lamella.

52. An electronic device comprising:
at least two interconnected nanostructures embedded in an encapsulating material; and
at least two metal contacts connected to the nanostructures,
   wherein the nanostructures and the metal contacts form an electrical connection such that the device is configured to allow an electrical current to flow through the device from one metal contact to the other via the interconnected nanostructures.

53. The electronic device according to item 52, wherein the two nanostructures are electrically connected by a superconducting material configured to achieve a superconducting state at a critical temperature, such that a superconducting gap is formed in the device at or below said temperature.

54. The electronic device according to any one of items 52-53, wherein the superconducting material is a metal, such as aluminium.

55. The electronic device according to any one of items 52-54, wherein the at least two interconnected nanostructures are InAs nanopillars.

1-16. (canceled)

17. A method of manufacturing a transferable lamella comprising interconnected nanostructures, the method comprising the steps of:
a) providing a planar substrate;
b) forming at least one superstructure on the substrate, said superstructure comprising a plurality of elongated nanostructures that elongates away from the substrate, wherein the elongated nanostructures are formed such that at least two of said nanostructures are conductively interconnected;
c) encapsulating at least a portion of said superstructure in an encapsulating material, said portion comprising at least two interconnected nanostructures; and
d) cutting the encapsulated superstructure in a direction that intersects at least two interconnected nanostructures, thereby manufacturing a transferable lamella comprising interconnected nanostructures.

18. The method of claim 17, wherein the superstructure is formed by growing a plurality of elongated nanostructures from the substrate.

19. The method of claim 18, wherein at least two of said elongated nanostructures are conductively interconnected at least partially along their growth direction.

20. The method of claim 19, wherein said at least two elongated nanostructures form an overlap in a plane parallel to the substrate, said overlap being between 1 nm and 1 μm.

21. The method of claim 17, wherein a first layer is grown or deposited to conductively interconnect or insulate at least a part of the elongated nanostructures as part of step b).

22. The method of claim 21, wherein the first layer is directionally deposited on one side of the nanostructures.

23. The method of claim 21, wherein a second layer is grown or deposited on the outside of the first layer to insulate the interconnected nanostructures.

24. The method of claim 21, wherein the first layer comprises a material selected from the group of superconductors, ferromagnetic materials, ferroelectric materials, and piezoelectric materials.

25. The method of claim 17, wherein the encapsulating material is electrically insulating with a resistivity of at least 10⁷ Ω·m.

26. The method of claim 17, wherein the superstructure comprises:
a plurality of elongated nanostructures of a semiconductor material; and
at least a first layer selected from the group of superconducting materials, ferromagnetic materials, and insulators.

27. The method of claim 26, wherein the first layer comprises a superconducting material, and wherein the superstructure comprises an interface between the semiconductor material and the first layer, said interface configured to provide a superconducting gap.

28. The method of claim 17, wherein the elongated nanostructures comprise an insulating core and a first layer selected from the group of semiconductors, superconducting materials, and ferromagnetic materials.

29. The method of claim 17, wherein at least a first layer is grown or deposited to conductively interconnect or insulate at least a part of the elongated nanostructures during forming of the at least one superstructure on the substrate.

30. The method of claim 17, wherein the encapsulating material is transparent to visible light.

31. A transferable lamella comprising conductively interconnected nanostructures embedded in an encapsulating material wherein the nanostructures extend between two opposing surfaces of the lamella, and wherein the nanostructures each have ends that are in the same plane as said opposing surfaces, and wherein the cross section of any of the nanostructures, in a plane parallel to the opposing surface, has an aspect ratio below 100.

32. The transferable lamella according to claim 31, wherein the cross section of any of the nanostructures, in a plane parallel to the opposing surface, has an aspect ratio below 10.

33. An electronic device comprising:
at least two interconnected nanostructures embedded in an encapsulating material wherein the nanostructures extend between two opposing surfaces of the lamella, and wherein the nanostructures each have ends that are in the same plane as said opposing surfaces, and wherein the cross section of any of the nanostructures, in a plane parallel to the opposing surface, has an aspect ratio below 100; and
at least two metal contacts connected to the nanostructures;
wherein the nanostructures and the metal contacts form an electrical connection such that the device is configured to allow an electrical current to flow through the device from one metal contact to the other via the interconnected nanostructures.

34. The electronic device according to claim 33, wherein the cross section of any of the nanostructures, in a plane parallel to the opposing surface, has an aspect ratio below 10.

35. A superstructure circuit, comprising:
at least one lamella according to claim 31 comprising multiple interconnected nanostructures;
at least two contacts in a conductive material, configured to form an electrical connection to points of the interconnected nanostructures of the lamella.
